(19) United States
(12) Patent Application Publication
(10) Pub. No.: US 2014/0110152 A1
(43) Pub. Date: Apr. 24, 2014

(54) PRINTED CIRCUIT BOARD AND METHOD FOR MANUFACTURING SAME

(71) Applicants: FUKUI PRECISION COMPONENT (SHENZHEN) CO., LTD., Shenzhen (CN); ZHEN DING TECHNOLOGY CO., LTD., Tayuan (TW)

(72) Inventors: QING ZUO, Shenzhen (CN); BIN-QIN LUO, Shenzhen (CN)

(73) Assignees: ZHEN DING TECHNOLOGY CO., LTD., Tayuan (TW); FUKUI PRECISION COMPONENT (SHENZHEN) CO., LTD., Shenzhen (CN)

(21) Appl. No.: 13/777,056

(22) Filed: Feb. 26, 2013

(30) Foreign Application Priority Data
Oct. 24, 2012 (CN) 2012104092978

(51) Int. Cl. H05K 1/02; H05K 3/00

(52) U.S. Cl. CPC H05K 1/0266; H05K 3/00
USPC 174/251; 156/252

(57) ABSTRACT

A printed circuit board includes a first outer electrically conductive pattern layer, a first insulation layer, a first inner electrically conductive pattern layer, a connection adhesive sheet, a second inner electrically conductive layer, a second insulation layer, a second outer electrically conductive pattern layer, and a identification mark, which are arranged in that order. The first outer electrically conductive pattern layer includes many first gold fingers. The second outer electrically conductive pattern layer includes many second gold fingers. The blind hole corresponds to the identification mark. The first outer electrically conductive pattern layer, the second outer electrically conductive pattern layer, and the at least one identification mark are simultaneously formed.

### BACKGROUND

1. Technical Field

The present disclosure generally relates to printed circuit boards (PCBs), and particularly to printed circuit board having gold fingers and a method for manufacturing the printed circuit board.

2. Description of Related Art

To accommodate development of miniaturized electronic products with multiple functions, printed circuit boards are widely used due to their special characteristics such as lightness and high-density interconnect-ability.

A typical printed circuit board is assembled to another printed circuit board or an electronic element via gold fingers under a process of hot pressure welding. In the process of the hot pressure welding, identification marks relating to gold fingers are needed to be formed on the printed circuit board, such that a welding machine can confirm the positions of the gold finger by identifying the positions of the identification marks, and then welds the printed circuit board to another printed circuit board or the electronic element. Therefore, position deviation between the gold fingers and the identification marks is limited to a smaller level, and a method for manufacturing the identification marks must have high precision. If the position deviation between the gold fingers and the identification marks is larger, the gold fingers of the printed circuit board cannot be well assembled to another printed circuit board or the electronic element in the hot pressure welding process.

What is needed, therefore, is a printed circuit board and a method for manufacturing the printed circuit board to overcome the above-described problems.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is a schematic, cross-sectional view of a first circuit substrate according to an exemplary embodiment.

FIG. 2 is a schematic, cross-sectional view of a second circuit substrate according to the exemplary embodiment.

FIG. 3 is a top view of the second circuit board of FIG. 2.

FIG. 4 is similar to FIG. 1, but showing a connection adhesive sheet formed on the first circuit substrate.

FIG. 5 is similar to FIG. 3, but showing an inner cover layer formed on the second circuit board.

FIG. 6 is similar to FIG. 4, but showing through holes defined in the first circuit board and the connection adhesive sheet.

FIG. 7 is a schematic, cross-sectional view of showing a lamination between the first circuit board and the second circuit substrate.

FIG. 8 is a schematic, cross-sectional view of a printed circuit board according to the exemplary embodiment.

FIG. 9 is a top view of the printed circuit board of FIG. 8.

FIG. 10 is a bottom view of the printed circuit board of FIG. 8.

FIG. 11 is similar to FIG. 8, but showing two outer cover layers formed on the two opposite sides of the printed circuit board.

FIG. 12 is a top view of the printed circuit board of FIG. 11 with the outer cover layers.

FIG. 13 is a bottom view of the printed circuit board of FIG. 11 with the outer cover layers.

### DETAILED DESCRIPTION

A printed circuit board and a method for manufacturing the printed circuit board according to embodiments will be described with reference to the drawings.

A method of manufacturing a printed circuit board according to an exemplary embodiment includes the steps as follows.

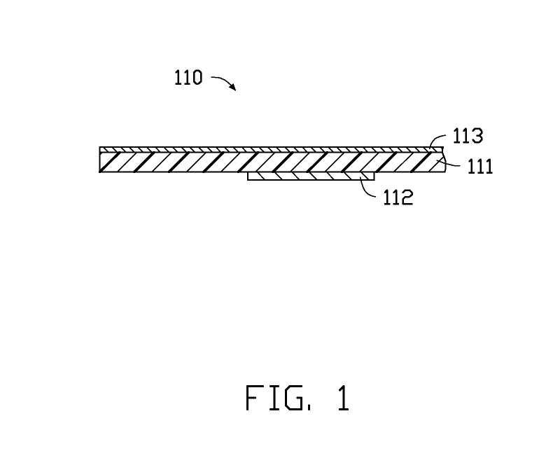

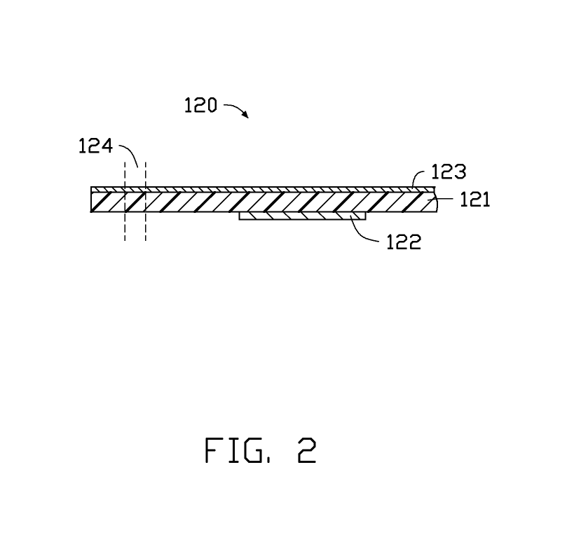

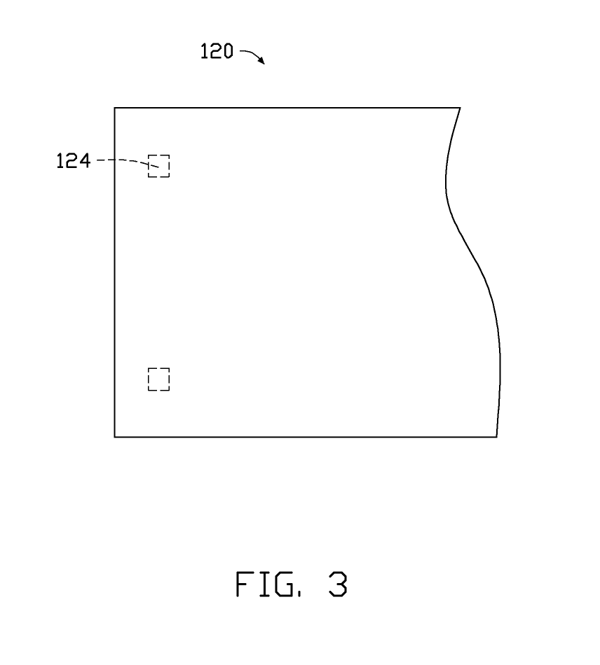

FIGS. 1 to 3 show step 1, in which a first circuit substrate 110 and a second circuit substrate 120 are provided.

In the present embodiment, the first circuit substrate 110 includes a first insulation layer 111, a first inner electrically conductive pattern layer 112, and a first copper foil 113. The first inner electrically conductive pattern layer 112 and the first copper foil 113 are formed at the opposite surfaces of the first insulation layer 111.

The shape and size of the second circuit substrate 120 are identical to the shape and size of the first circuit substrate 110. The second circuit substrate 120 includes a second insulation layer 121, a second inner electrically conductive pattern layer 122, and a second copper foil 123. The second inner electrically conductive pattern layer 122 and the second copper foil 123 are formed on the opposite surfaces of the second insulation layer 121. The second circuit substrate 120 includes at least one marking region 124. There is no the second electrically conductive pattern layer 122 in the marking region 124. That is, the marking region 124 consists of the second insulation layer 121 and the second copper foil 123. In the present embodiment, there are two marking regions 124 separated from each other. Each of the marking regions 124 is in the shape of a square, and the side length of the marking regions 124 is in a range from 0.8 millimeters to 1.0 millimeters. In other embodiments, the marking region 124 may be a round marking region, or a triangle marking region, or a hexagonal making region, for example.

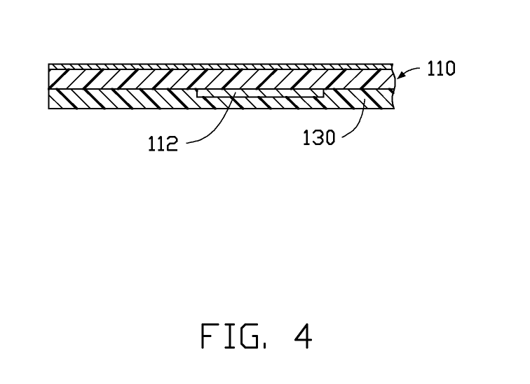

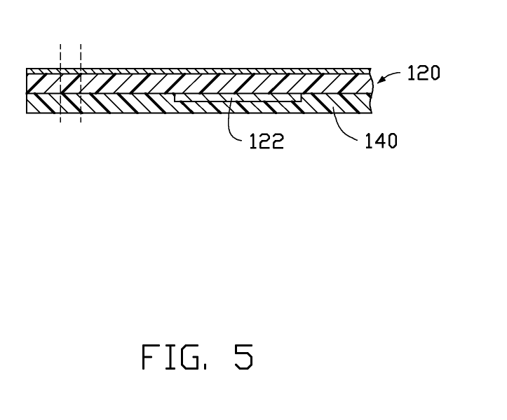

FIGS. 4 to 5 show step 2, in which a connection adhesive sheet 130 is attached on the first inner electrically conductive pattern layer 112 and the surface of the first circuit substrate 110 exposed at the first inner electrically conductive pattern layer 112, and an inner cover layer 140 is formed at the second inner electrically conductive pattern layer 122 and the surface of the second circuit substrate 120 exposed at the second inner electrically conductive pattern layer 122. The connection adhesive sheet 130 may be a prepreg.

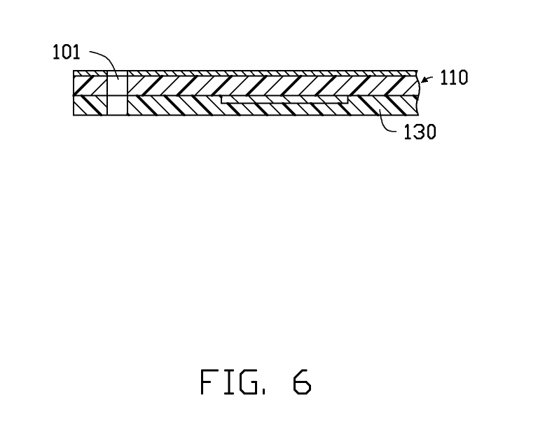

FIG. 6 shows step 3, in which at least one through hole 101 is defined in the first circuit substrate 110 having the connection adhesive sheet 130. The number of the through holes 101 is identical to the number of the marking regions 124. The through holes 101 spatially correspond to the marking regions 124, and each through hole 101 passes through the connection adhesive sheet 130 and the first circuit substrate 110.

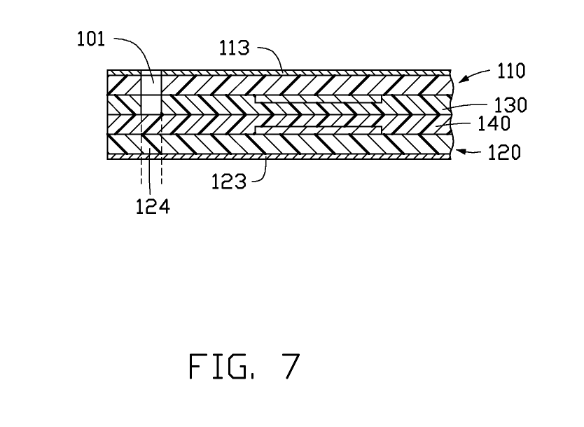

FIG. 7 shows step 4, in which the first circuit substrate 110 is laminated onto the second circuit substrate 120, such that the connection adhesive sheet 130 is in contact with the inner cover layer 140. After lamination, the through holes 101 are respectively aligned with the marking regions 124.

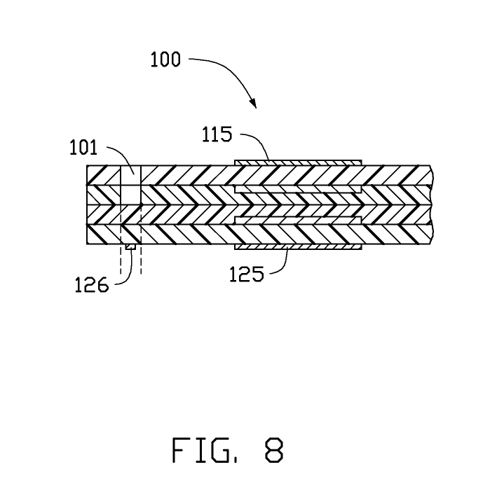

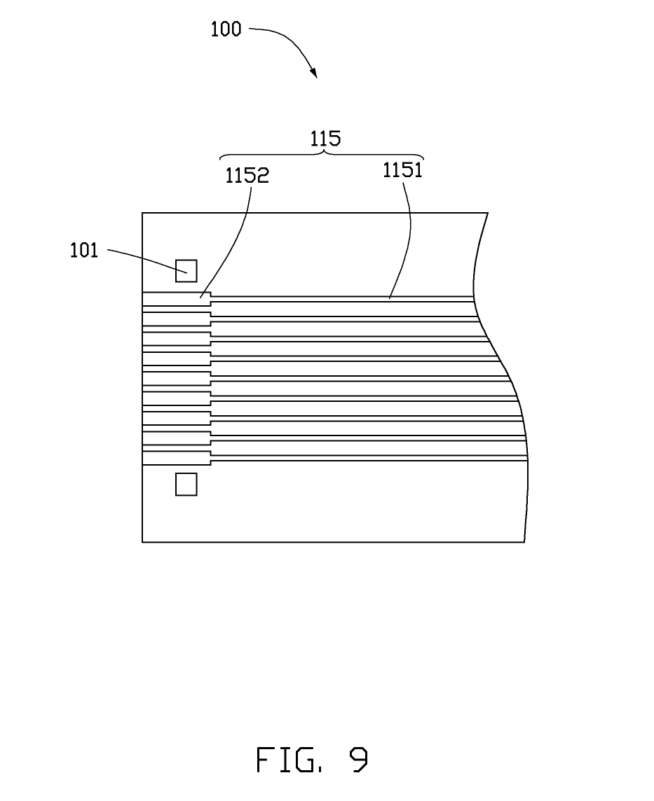

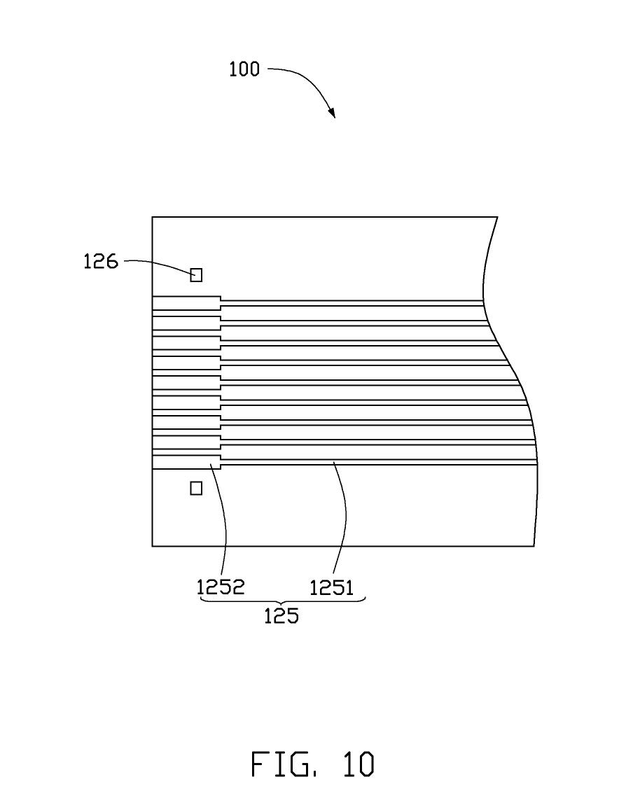

FIGS. 8-10 show step 4, in which the first copper foil 113 is converted into a first outer electrically conductive pattern layer 115, and the second copper foil 123 is converted into a second outer electrically conductive pattern layer 125 with at least one identification mark 126, thereby obtaining a printed circuit board 100. The number of the identification marks 126 is identical to the number of the marking regions 124. The identification marks 126 are respectively arranged in the marking regions 124. In the present embodiment, a shape of the identification mark 126 is the same as a shape of a cross-section of the through hole 101 taken in a plane parallel with the first insulation layer 111, and a size of the identification mark 126 is smaller than a size of the cross-section of the corresponding through hole 101 taken in a plane parallel with the first insulation layer 111.

In the present embodiment, the first outer electrically conductive pattern layer 115, the second outer electrically conductive pattern layer 125, and the at least one identification mark 126 are simultaneously formed by an image-transfer process and a etching process.

The first outer electrically conductive pattern layer 115 includes a plurality of first electrically conductive traces 1151, and a plurality of first gold fingers 1152. The first gold fingers 1152 spatially correspond the first electrically conductive traces 1151, and the first gold fingers 1152 are respectively in contact with and electrically connected to the first electrically conductive traces 1151. In the present embodiment, the first gold fingers 1152 are positioned between the two through holes 101.

The second outer electrically conductive pattern layer 125 includes a plurality of second electrically conductive traces 1251, and a plurality of second gold fingers 1252. The second gold fingers 1252 spatially correspond the second electrically conductive traces 1251, and the second gold fingers 1252 are respectively in contact with and electrically connected to the second electrically conductive traces 1251. The second copper foil 123 in the marking region 124 is etched to be an identification mark 126. In the present embodiment, the identification mark 126 is also in the shape of a square, and the side length of the identification mark 126 is in a range from 0.5 millimeters to 0.8. That is, the shape of the identification mark 126 is the same as the shape of the marking region 124, and the size of the identification mark 126 is smaller than the size of the marking region 124.

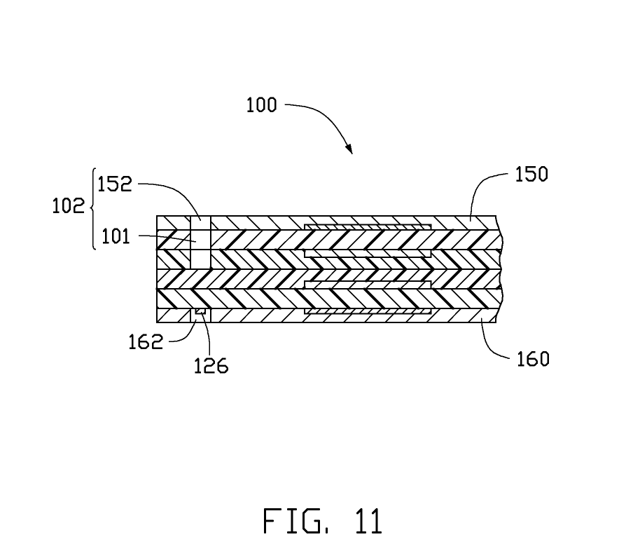

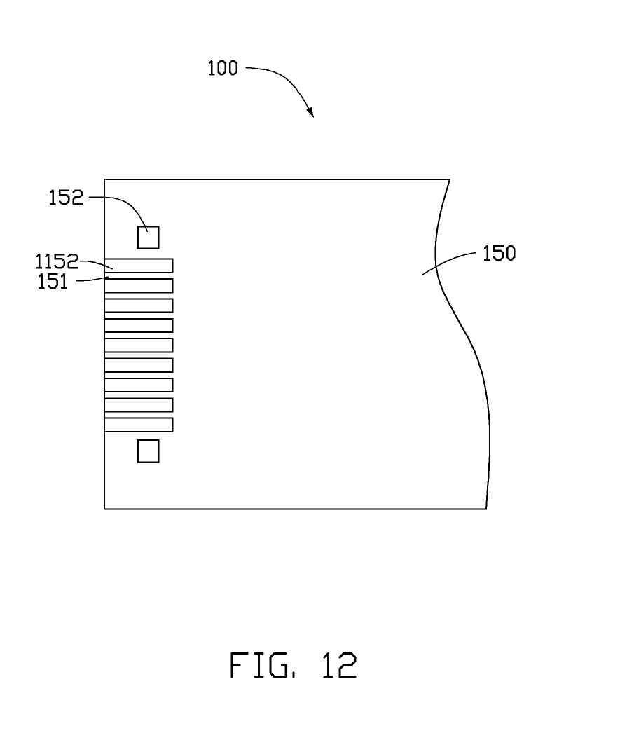

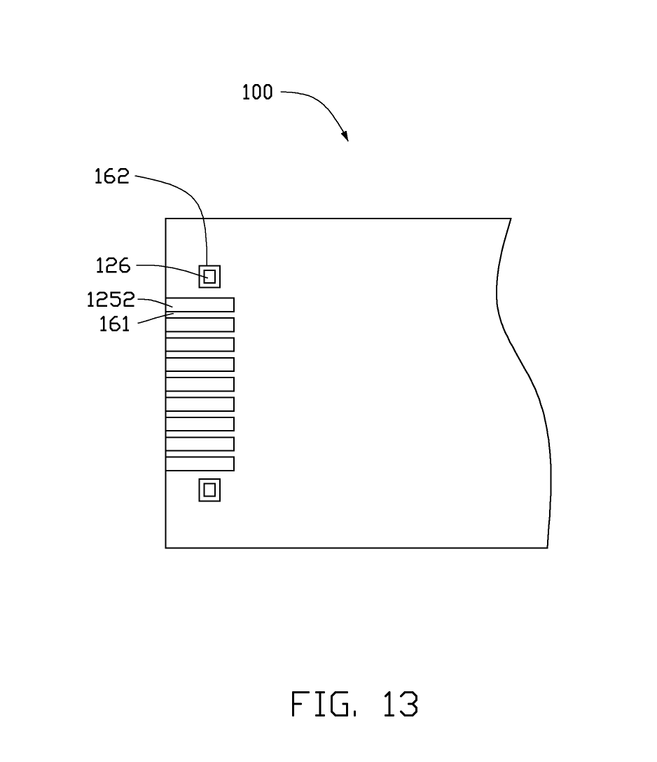

FIGS. 11 to 13 show, in the present embodiment, the method for manufacturing the printed circuit board 100 may further include a step 6 of forming a first outer cover layer 150 at a side of the first outer electrically conductive pattern layer 115, and a second outer cover layer 160 at a side of the second outer electrically conductive pattern layer 125. A plurality of first openings 151 and a plurality of second opening 152 are defined in the first outer cover layer 150. The first openings 151 spatially correspond to the first gold fingers 1152, and the first gold finger 1152 are respectively exposed through the first openings 151. The second openings 152 spatially correspond to the through holes 101, and the second opening 152 respectively communicates with the through holes 101. A plurality of third openings 161 and fourth openings 162 are defined in the second outer cover layer 160. The third openings 161 spatially correspond to the second gold fingers 1252, and the second gold fingers 1252 are respectively exposed through the third openings 161. The fourth openings 162 spatially correspond to the identification marks 126, and identification mark 126 are respectively exposed through the fourth openings 162. A size of a cross-section of each fourth opening 162 taken in a plane parallel with the second insulation layer 121 is larger than a size of the corresponding identification mark 126. A size of the cross-section of each fourth opening 162 taken in a plane parallel with the second insulation layer 121 is identical to the corresponding marking region 124.

In alternative embodiments, the method for manufacturing the printed circuit board 100 may be used for manufacturing another multi-layered printed circuit board, which has more electrically conductive pattern layer than the printed circuit board 100. That is, when the first circuit substrate 110 is laminated onto the second circuit substrate 120, there may be one or more third circuit substrates between the first circuit substrate 110 and the second circuit substrate 120, and there may be another connection adhesive sheet between two adjacent third circuit substrates. Each third circuit substrate may includes a third insulation layer and at least one third inner electrically conductive pattern layer formed at a side of the third insulation layer, and at least one second through hole is defined in the third circuit substrate. The at least one second through hole corresponds to the at least one marking region 124. After lamination, step 5 to step 6 can successively be processed to form another multi-layered printed circuit board having more electrically conductive pattern layer than the printed circuit board 100.

In further alternative embodiments, the step of forming the inner cover layer 140 on the side of the second inner electrically conductive pattern layer 120 of the second circuit substrate 120 may be omitted, in such case, there is only the connection adhesive sheet 130 between the first inner electrically conductive pattern layer 112 and the second inner electrically conductive pattern layer 122.

The printed circuit board 100 manufactured by the above method includes the first outer electrically conductive pattern layer 115, the first insulation layer 111, the first inner electrically conductive pattern layer 112, the connection adhesive sheet 130, the inner cover layer 140, the second inner electrically conductive layer 122, the second insulation layer 121, the second outer electrically conductive pattern layer 125, and at least one identification mark 126, which are arranged in that order. At least one blind hole 102 is formed in the printed circuit board 100. The blind hole 102 only passes through the first outer electrically conductive pattern layer 115 and the connection adhesive sheet 130. The first outer electrically conductive pattern layer 115 includes the first electrically conductive traces 1151 and the first gold fingers 1152. The second outer electrically conductive pattern layer 125 includes the second electrically conductive trace 1251 and the second gold fingers 1252. The at least one identification mark 126 corresponds to the at least one blind hole 102. The identification mark 126 is formed on the second insulation layer 121. The first outer electrically conductive pattern layer 115, the second outer electrically conductive pattern layer 125, and the identification mark 126 are simultaneously formed. The second insulation layer 121 and the inner cover layer 140 are made of a transparent material, for example, Polyimide, or Polyester, for example.

The printed circuit board 100 also includes the first outer cover layer 150 and the second outer cover layer 160. The first outer cover layer 150 is formed at a side of the first outer electrically conductive pattern layer 115, and the second outer cover layer 160 is formed at a side of the second outer electrically conductive pattern layer 125. The first openings 151 and the second opening 152 are defined in the first outer cover layer 150. The first openings 151 spatially correspond to the first gold fingers 1152, and the first gold finger 1152 are respectively exposed through the first openings 151. The second openings 152 spatially correspond to the through holes 101, and the second openings 152 respectively communicates with the through holes 101. The third openings 161 and the fourth openings 162 are defined in the second outer cover layer 160. The third openings 161 spatially correspond to the second gold fingers 1252, and the second gold fingers 1252 are respectively exposed through the third openings 161. The fourth openings 162 spatially correspond to the identification marks 126, and the size of each fourth opening 162 is larger than the size of the corresponding identification mark 126. The size of each fourth opening 162 is identical to the size of the corresponding marking region 124.

In other embodiments, the printed circuit board 100 may have more electrically conductive pattern layer. That is, there may be more inner electrically conductive pattern layers and insulation layers alternatively formed between the connection adhesive sheet 130 and the inner cover layer 140. The blind hole 102 passes through the inner electrically conductive pattern layers and insulation layers alternatively formed.

In the present embodiment, the second insulation layer 121 and the inner cover layer 140 are made of a transparent material, for example, Polyimide, or Polyester, for example. In the hot pressure welding process, it is very easy for the welding machine to identify the identification mark 126.

Because the identification mark 126, the first gold fingers 1152, and the second gold fingers 1252 are formed simultaneously, the position deviation between the identification mark 126, the first gold finger 1152, and the second gold finger 1252 is smaller, and making precision of the identification mark 126 is higher.

While certain embodiments have been described and exemplified above, various other embodiments will be apparent from the foregoing disclosure to those skilled in the art. The disclosure is not limited to the particular embodiments described and exemplified but is capable of considerable variation and modification without departure from the scope and spirit of the appended claims.

What is claimed is:

1. A method for manufacturing a printed circuit board, comprising:
providing a first circuit board and a second circuit board, the first circuit substrate comprising a first insulation layer, a first inner electrically conductive pattern layer, and a first copper foil, the second circuit substrate comprising a second insulation layer, a second inner electrically conductive pattern layer, and a second copper foil, the second circuit substrate comprising at least one marking region, the marking region consisting of the second insulation layer and the second copper foil;
attaching a connection adhesive sheet on the first inner electrically conductive pattern layer and the surface of the first circuit substrate exposed at the first inner electrically conductive pattern layer, and defining at least one through hole in the first circuit substrate, the through hole passing through the connection adhesive sheet and the first circuit substrate, and spatially corresponding to the at least marking region;
laminating the first circuit substrate onto the second circuit substrate, such that the connection adhesive sheet is sandwiched between the first circuit substrate and the second circuit substrate, and the through hole aligned with the marking region; and
converting the first copper foil into a first outer electrically conductive pattern layer, and converting the second copper foil into a second outer electrically conductive pattern layer with at least one identification mark, the identification mark being arranged in the marking region, the first outer electrically conductive pattern layer comprising a plurality of first gold fingers, the second outer electrically conductive pattern layer comprising a plurality of second gold fingers.

2. The method of claim 1, wherein the second insulation layer is made of transparent material.

3. The method of claim 1, wherein a shape of the identification mark is the same as a shape of a cross-section of the corresponding through hole taken in a plane parallel with the first insulation layer, and a size of the identification mark is smaller than a size of the cross-section of the corresponding through hole taken in a plane parallel with the first insulation layer.

4. The method of claim 1, wherein before laminating the first circuit substrate onto the second circuit substrate, the method further comprises a step of attaching an inner cover layer on the second inner electrically conductive pattern layer and the surface of the second circuit substrate exposed at the second inner electrically conductive pattern layer, and when the first circuit substrate is laminated onto the second circuit substrate, the connection adhesive sheet is in contact with the inner cover layer.

5. The method of claim 1, wherein the first outer electrically conductive pattern layer further comprises a plurality of first electrically conductive traces, the first electrically conductive traces are respectively electrically connected to the corresponding first electrically conductive trace, the second outer electrically conductive pattern layer further comprises a plurality of second electrically conductive traces, the second electrically conductive traces are respectively electrically connected to the corresponding second electrically conductive trace.

6. The method of claim 1, wherein the at least marking region comprises a plurality of marking regions, the at least through hole comprises a plurality of through holes, the method further comprises a step of forming a first outer cover layer on the first outer electrically conductive pattern layer, and a second outer cover layer on the second outer electrically conductive pattern layer, a plurality of first openings and a plurality of second opening are defined in the first outer cover layer, the first openings spatially corresponds to the first gold fingers, and first gold fingers are respectively exposed through the first openings, the second openings spatially correspond to the through holes, and second openings respectively communicates with the through holes, a plurality of third openings and fourth openings are defined in the second outer cover layer, the third openings spatially correspond to the second gold fingers, and gold fingers are respectively exposed through the third openings, the fourth openings spatially correspond to the identification marks, and the identification marks are respectively exposed through the fourth openings.

7. The method of claim 6, wherein a size of a cross-section of each fourth opening taken in a plane parallel with the second insulation layer is larger than a size of the corresponding identification mark, and a size of the cross-section of each fourth opening taken in a plane parallel with the second insulation layer is identical to the corresponding marking region.

8. The method of claim 1, wherein the first outer electrically conductive pattern layer, the second outer electrically conductive pattern layer, and the at least one identification mark are made using an image-transfer process and an etching process.

9. A printed circuit board, comprising a first outer electrically conductive pattern layer, a first insulation layer, a first inner electrically conductive pattern layer, a connection adhesive sheet, a second inner electrically conductive layer, a second insulation layer, a second outer electrically conductive pattern layer, and at least one identification mark which are arranged in that order, at least one blind hole being defined in the printed circuit board, and passing through the first outer electrically conductive pattern layer, the first insulation layer, the first inner electrically conductive pattern layer, and the connection adhesive sheet, the first outer electrically conductive pattern layer comprising a plurality of first gold fingers, the second outer electrically conductive pattern layer comprising a plurality of second gold fingers, the at least one blind hole corresponding to the at least one identification mark, the first outer electrically conductive pattern layer, the second outer electrically conductive pattern layer, and the at least one identification mark being simultaneously formed.

10. The printed circuit board of claim 9, wherein the printed circuit board further comprises an inner cover layer sandwiched between the connection adhesive sheet and the second inner electrically conductive pattern layer.

11. The printed circuit board of claim 9, wherein the second insulation layer is made of transparent material.

12. The printed circuit board of claim 9, wherein a shape of the identification mark is the same as a shape of a cross-section of the corresponding through hole taken in a plane parallel with the first insulation layer, and a size of the identification mark is smaller than a size of the cross-section of the corresponding through hole taken in a plane parallel with the first insulation layer.

13. The printed circuit board of claim 9, wherein the printed circuit board further comprises a first outer cover layer and a second outer cover layer, the first outer cover layer is formed on the first outer electrically conductive pattern layer, the second outer cover layer is formed on the second outer electrically conductive pattern layer, a plurality of first openings and a plurality of second opening are defined in the first outer cover layer, the first openings spatially corresponds to the first gold fingers, and first gold fingers rare respectively exposed through the first openings, the second openings spatially correspond to the through holes, and the second openings respectively communicate with the through holes, a plurality of third openings and fourth openings are defined in the second outer cover layer, the third openings spatially correspond to the second gold fingers, and the second gold fingers are respectively exposed through the third openings, the fourth openings spatially correspond to the identification marks, and the identification marks are respectively exposed through the fourth openings.

14. The printed circuit board of claim 9, wherein a size of a cross-section of each fourth opening taken in a plane parallel with the second insulation layer is larger than a size of the corresponding identification mark, and a size of the cross-section of each fourth opening taken in a plane parallel with the second insulation layer is identical to the corresponding marking region.
